(19) United States
(12) Patent Application Publication
(10) Pub. No.: US 2011/0266542 A1
(43) Pub. Date: Nov. 3, 2011

(54) SEMICONDUCTOR DEVICE AND METHOD OF FABRICATING THE SAME

(75) Inventors: Min Ki RYU, Seoul (KR); Sang Hee Park, Daejeon (KR); Chi Sun Hwang, Daejeon (KR); Kyoung Ik Cho, Daejeon (KR)

(73) Assignee: ELECTRONICS AND TELECOMMUNICATIONS RESEARCH INSTITUTE, Daejeon (KR)

(21) Appl. No.: 13/094,933

(22) Filed: Apr. 27, 2011

(30) Foreign Application Priority Data
Apr. 28, 2010 (KR) 10-2010-0039411

(51) Int. Cl. H01L 29/04; H01L 21/336

(52) U.S. Cl. 257/57; 257/66; 438/157; 257/E29.003; 257/E21.421

(57) ABSTRACT

Provided are a semiconductor device including a dual gate transistor and a method of fabricating the same. The semiconductor device includes a lower gate electrode, an upper gate electrode on the lower gate electrode, a contact plug interposed between the lower gate electrode and the upper gate electrode, and connecting the lower gate electrode to the upper gate electrode, and a functional electrode spaced apart from the upper gate electrode and formed at the same height as the upper gate electrode. The dual gate transistor exhibiting high field effect mobility is applied to the semiconductor device, so that characteristics of the semiconductor device can be improved. In particular, since no additional mask or deposition process is necessary, a large-area high-definition semiconductor device can be mass-produced with neither an increase in process cost nor a decrease in yield.

### CROSS-REFERENCE TO RELATED APPLICATION

This application claims priority to and the benefit of Korean Patent Application No. 10-2010-0039411, filed Apr. 28, 2010, the disclosure of which is incorporated herein by reference in its entirety.

### BACKGROUND

1. Field of the Invention

The present invention relates to a semiconductor device and a method of fabricating the same, and in particular, to a semiconductor device including a dual gate transistor and a method of fabricating the same.

2. Discussion of Related Art

Recently, an amorphous silicon transistor and a polysilicon transistor have been applied to a flat panel display such as a liquid crystal display device and an organic light emitting diode (OLED) display device. While amorphous silicon is appropriate to a large-area process due to excellent uniformity, it exhibits low field effect mobility. Further, while polysilicon exhibits high field effect mobility and excellent reliability, it is not appropriate to a large-area process due to low uniformity.

Therefore, in the related art, a method of applying an oxide semiconductor transistor having advantages of amorphous silicon and polysilicon is proposed. An oxide semiconductor transistor is appropriate to a large-area process due to high uniformity, and exhibits high reliability. However, the oxide semiconductor transistor exhibits a field effect mobility of 10 to 20 cm²/Vs, which is lower than that of a polysilicon transistor.

Therefore, in order to provide a large-area, high-definition display device, it is necessary to apply a transistor exhibiting high field effect mobility to the display device. Obviously, such a demand is not be limited to the display device alone, and thus is equally applied to a semiconductor device such as a sensor.

### SUMMARY OF THE INVENTION

The present invention is directed to a semiconductor device including a dual gate transistor, in which a channel resistance is lowered to enhance field effect mobility, and a method of fabricating the same.

An aspect of the present invention provides a semiconductor device including: a lower gate electrode; an upper gate electrode on the lower gate electrode; a contact plug interposed between the lower gate electrode and the upper gate electrode and connecting the lower gate electrode to the upper gate electrode; and a functional electrode spaced apart from the upper gate electrode and formed at the same height as the upper gate electrode.

Another aspect of the present invention provides a method of fabricating a semiconductor device including: forming a lower gate electrode; forming a gate insulating layer on an entire surface of the resultant structure in which the lower gate electrode is formed; forming a conductive layer for an electrode on the gate insulating layer; and etching the conductive layer for an electrode to form an upper gate electrode located above the lower gate electrode and a functional electrode spaced apart from the upper gate electrode at the same time.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A to 1C illustrate the structure of a semiconductor device according to an exemplary embodiment of the present invention;

FIGS. 2A to 2H illustrate a method of fabricating a semiconductor device according to a first exemplary embodiment of the present invention; and

FIGS. 3A to 3C illustrate a method of fabricating a semiconductor device according to a second exemplary embodiment of the present invention.

### DETAILED DESCRIPTION OF EXEMPLARY EMBODIMENTS

Various exemplary embodiments will now be described more fully with reference to the accompanying drawings in which some exemplary embodiments are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thickness of layers and regions may be exaggerated for clarity. Also, when it is referred that a layer is “on” another layer or a substrate, it may be directly formed on another layer or the substrate or a third layer may be interposed therebetween. Like reference numerals designate like elements throughout the specification.

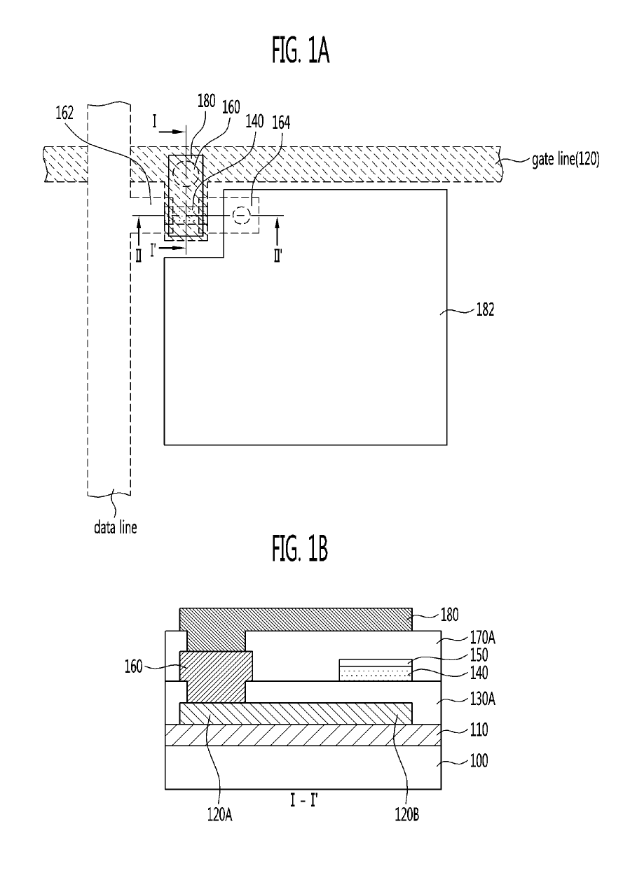

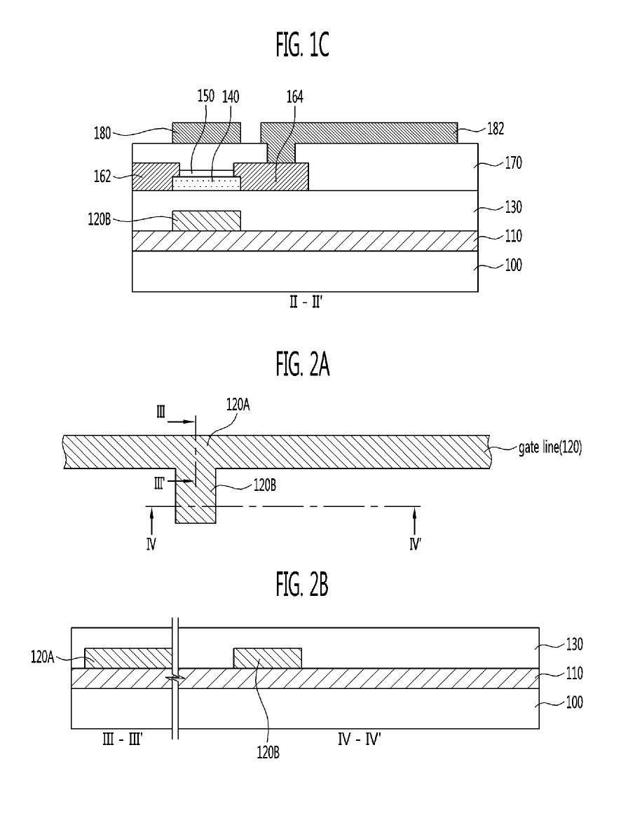

FIGS. 1A to 1C illustrate the structure of a semiconductor device according to an exemplary embodiment. FIG. 1A is a plan view illustrating a semiconductor device in which a dual gate transistor and a first functional electrode are formed, FIG. 1B is a cross-sectional view taken in a first direction (line I-I′) of FIG. 1A, and FIG. 1C is a cross-sectional view taken in a second direction (line II-II′) of FIG. 1A.

As illustrated, a semiconductor device according to an exemplary embodiment of the present invention includes a lower gate electrode 120, an upper gate electrode 180 formed on the lower gate electrode 120, a contact plug 160 connecting the lower gate electrode 120 to the upper gate electrode 180, and a first functional electrode 182 formed to be spaced apart from the upper gate electrode 180 at the same height as the upper gate electrode 180.

According to such a structure, since the lower gate electrode 120 is electrically connected to the upper gate electrode 180 by the contact plug 160, the lower gate electrode 120 and the upper gate electrode 180 are simultaneously driven. Meanwhile, a conventional dual gate transistor is generally configured so that a voltage is independently applied to drive a lower gate electrode and an upper gate electrode. However, in the dual gate transistor according to an exemplary embodiment, both the lower gate electrode and the upper gate electrode are simultaneously driven. Also, the dual gate transistor may further include a source electrode 162 and a drain electrode 160 formed at the same height as the contact plug 160 so as to be spaced apart from the contact plug 160, a channel layer 140 formed between the source and drain electrodes 162 and 164, and a passivation layer 150 formed on the channel layer 140.

Here, a gate line is for transmitting a gate signal, and is in the shape of a line extending in the second direction (II-II′), and a data line is for transmitting a data signal, and is in the shape of a line extending in the first direction (I-I′).

The semiconductor device having the above-described structure may have numerous applications such as a display device, a sensor, etc.

For example, when the semiconductor device is an organic light-emitting diode (OLED) display device that is a display device to which an organic light-emitting device is applied, the first functional electrode 182 is used as a pixel electrode. Further, the semiconductor device further includes an organic light-emitting layer and a common electrode formed on the first functional electrode 182.

As another example, when the semiconductor device is a display device to which a liquid crystal display device is applied, the first functional electrode 182 is used as a pixel electrode. In addition, the semiconductor device further includes an alignment layer, a short portion, a sealant and a spacer formed on the first functional electrode 182. The semiconductor device further includes a color filter substrate including a common electrode and a color filter, and a liquid crystal layer.

As still another example, when the semiconductor device is a sensor, the first functional electrode 182 is used as a lower electrode of the sensor. Further, the semiconductor device further includes a spacer formed on the first functional electrode 182 and an upper electrode of the sensor.

In particular, the present invention may be applied to an optical sensor in addition to a contact-type sensor and a capacitive-type sensor.

As a result of applying the dual gate transistor having a low channel resistance to the display device and the sensor, the display device may provide high definition and a large area, and performance of the sensor may be improved.

Specifically, since a conventional single gate transistor has a low field effect mobility of 10 to 20 cm2/Vs, there is a limit to realization of a large-area and high-definition display device and a sensor. In contrast, the dual gate transistor whose field effect mobility is twice or more that of the single gate transistor is used in the present invention.

The conventional single gate transistor includes a channel layer, a gate insulating layer, and a gate electrode. When an electric field is applied to the gate electrode, electric charges are accumulated on the channel layer around an interface between the gate electrode and the gate insulating layer. However, since the dual gate transistor includes a lower gate electrode, a first gate insulating layer, a channel layer, a second gate insulating layer and an upper gate electrode, electric charges are accumulated at a lower interface of the channel layer contacting the first gate insulating layer as well as at an upper interface of the channel layer contacting the second gate insulating layer. Therefore, compared with the single gate transistor, the dual gate thin film transistor has a double region where electric charges are movable, and thus a channel resistance of the device is reduced by half.

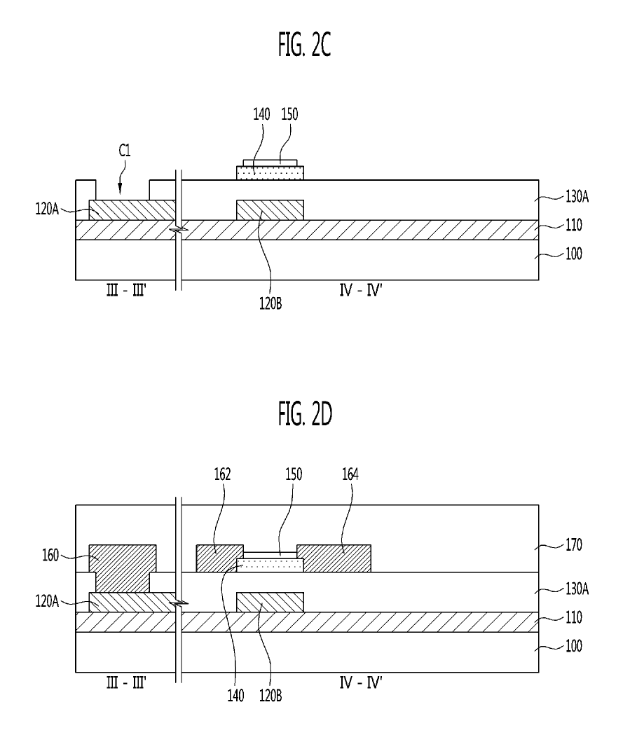

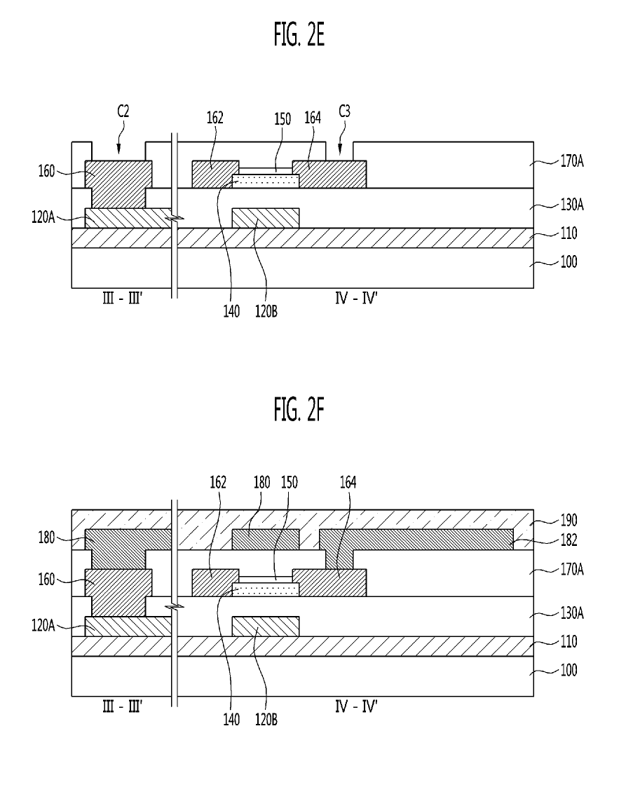

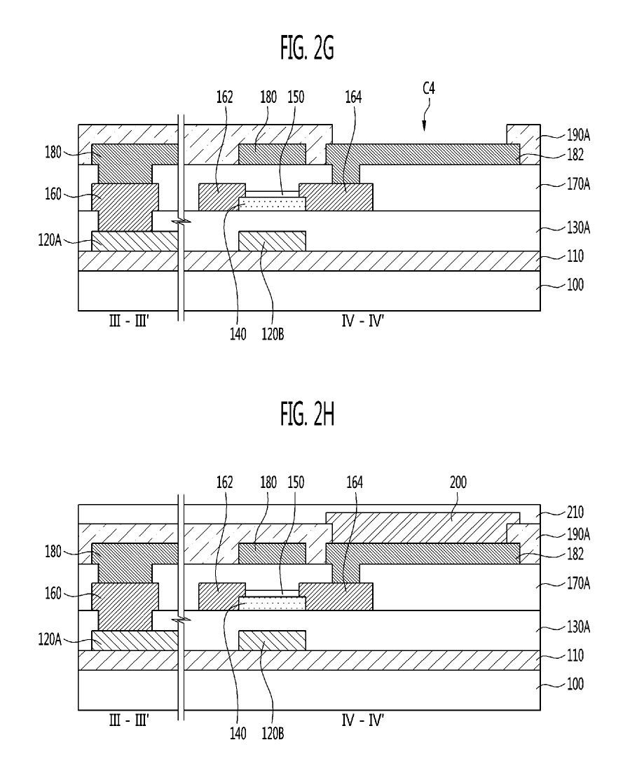

FIGS. 2A to 2H illustrate a method of fabricating a semiconductor device according to a first exemplary embodiment of the present invention.

Here, FIG. 2A is a plan view of a semiconductor device in which a gate line is formed, and FIGS. 2B to 2H are cross-sectional views taken in a third direction (III-III′) and a fourth direction (IV-IV′) of FIG. 2A for clarity.

As illustrated in FIGS. 2A and 2B, a buffer layer 110 is formed on a substrate 100. Here, for example, the substrate 100 may be a glass substrate or a plastic substrate. The buffer layer 110 is for preventing the diffusion of moisture or impurities from the substrate 100, and for example, it may be formed of a single insulating layer such as a silicon oxide layer, a silicon nitride layer or an aluminum oxide layer, or a stacked layer thereof.

Then, a conductive layer for the lower gate electrode is formed on the buffer layer 110, and is patterned to form lower gate electrodes 120A and 120B of the dual gate transistor. Here, as illustrated in FIG. 2A, the lower gate electrodes 120A and 120B may be formed to have a line portion and a protrusion portion protruding from the line portion, i.e., may be formed as a T-shaped gate line 120. For convenience of description, the protruding portion of the gate line 120 will be indicated by 120B, and the line portion adjacent to the protrusion portion will be indicated by 120A. That is, it is illustrated in FIG. 2B that the lower gate electrodes 120A and 120B are divided into two regions. However, it should be noted that these regions are one pattern.

The lower gate electrodes 120A and 120B may be formed of an aluminum alloy single layer such as aluminum (Al) or aluminum-neodymium (Al—Nd) or multiple layers in which a molybdenum (Mo) alloy and an Al alloy are stacked. Further, when the lower gate electrodes 120A and 120B are transparent, they may be formed of a single layer of an Indium Tin Oxide (ITO) layer or multiple layers in which a silver alloy layer and an ITO layer are stacked.

Then, a first gate insulating layer 130 is formed on the entire surface of a resultant structure in which the lower gate electrodes 120A and 120B are formed. Here, for example, the first gate insulating layer 130 may be formed of either a single layer such as a silicon oxide (SiO₂) layer, a silicon nitride (SiN) layer or an aluminum oxide (Al₂O₃) layer, or a stacked layer thereof.

As illustrated in FIG. 2C, a material layer for a channel and a passivation layer are formed on the entire surface of the first gate insulating layer 130, and then is patterned. As a result, a channel layer 140 partially overlapping a lower gate electrode 120B and a passivation layer 150 are formed on the first gate insulating layer 130. That is, the channel layer 140 and the passivation layer 150 are formed above the part of the lower gate electrode 120B corresponding to the protrusion portion of the lower gate electrode.

Here, in order to electrically connect the channel layer 140 to a source electrode and a drain electrode that are to be formed in the subsequent process, the passivation layer 150 may be patterned such that both ends of the channel layer 140 are partially exposed.

The channel layer 140 may be formed of oxide semiconductor. For example, it may be formed of a zinc oxide (ZnO) layer, a zinc tin oxide (ZTO), or indium gallium zinc oxide (IGZO) layer or a zinc indium tin oxide (ZITO) layer, and here, boron (B), Al, silicon (Si), germanium (Ge), titanium (Ti), zirconium (Zr) or hafnium (Hf) may be doped thereinto.

The passivation layer 150 may be formed of a single layer of a SiO₂ layer, a SiN layer or an Al₂O₃ layer or may be formed of a stacked layer thereof.

Then, the first gate insulating layer 130 is etched to form a first contact hole C1 exposing the surface of the first functional electrode 120A. Here, the first contact hole C1 is formed such that the surface of the lower gate electrode 120A corresponding to the line region contacting the protrusion portion of the lower gate electrode is exposed.

In FIG. 2C, the first gate insulating layer etched in the process of forming the first contact hole C1 is indicated by 130A.

As illustrated in FIG. 2D, a conductive layer for a contact is formed on the first gate insulating layer 130A in which the first contact hole C1 is formed. Here, the conductive layer for a contact is buried in the first contact hole C1.

Then, the conductive layer for a contact is etched to form a contact plug 160 connected to the lower gate electrode 120A, and at the same time, a source electrode 162 and a drain electrode 164 are formed away from the contact plug 160. That is, the contact plug 160, the source electrode 162 and the drain electrode 164 are simultaneously formed through one deposition process and one mask process. As a result, the contact plug 160, the source electrode 162 and the drain electrode 164 are formed of the same material. Here, the source electrode 162 and the drain electrode 164 are formed to be in contact with both ends of the channel layer 140.

As a result, the source electrode 162 and the drain electrode 164 spaced apart from the contact plug 160 are formed at substantially the same height as the contact plug 160. Here, substantially the same height refers to the same height within a tolerance range taking into account height deviation of a pattern caused by the limitation of the process.

Here, the source electrode 162 and the drain electrode 164 may be formed of a single layer such as an Al layer or an Al—Nd layer, or multiple layers in which a Mo alloy layer and an Al alloy layer are stacked. Further, when the source electrode 162 and the drain electrode 164 are formed to be transparent, they may be formed of a single layer of an ITO layer or multiple layers in which a silver alloy layer and an ITO layer are stacked.

Afterwards, a second gate insulating layer 170 is formed on the entire surface of the resultant structure in which the source electrode 162 and the drain electrode 164 are formed.

Here, the second gate insulating layer 170 may be formed of a single layer such as a SiO₂ layer, a SiN layer or an Al₂O₃ layer, or a stacked layer thereof. Moreover, the second gate insulating layer 170 and the passivation layer 150 may have a capacitance per unit area similar to that of the first gate insulating layer 130A.

As illustrated in FIG. 2E, the second gate insulating layer 170 is etched to form a second contact hole C2 exposing the surface of the contact plug 160, and at the same time, a third contact hole C3 exposing the surface of the source electrode 162 or drain electrode 164 is formed.

In FIG. 2E, as an example of the third contact hole C3, the case in which the third contact hole C3 exposes the surface of the drain electrode 164 is illustrated. Further, in FIG. 2E, the second gate insulating layer etched in the process of forming the second and third contact holes C2 and C3 is indicated by 170A.

As illustrated in FIG. 2F, a conductive layer for an electrode is formed on the second gate insulating layer 170A in which the second and third contact holes C2 and C3 are formed. Then, the conductive layer for an electrode is etched to form an upper gate electrode 180 located above a part of the lower gate electrode 120A and a first functional electrode 182 spaced apart from the upper gate electrode 180. That is, the upper gate electrode 180 and the first functional electrode 182 are simultaneously formed using a deposition process and a mask process, and accordingly, the upper gate electrode 180 and the first functional electrode 182 are formed at substantially the same height. Furthermore, the upper gate electrode 180 and the first functional electrode 182 formed of the same material are formed.

Here, the upper gate electrode 180 is electrically connected to the lower gate electrode 120A through the contact plug 160. As a result, the dual gate transistor including the lower gate electrode 120A and the upper gate electrode 180 connected to each other by the contact plug 160 is formed.

The first functional electrode 182 may be a pixel electrode of a display such as an OLED display device or a liquid crystal display device, and may be electrically connected to the source electrode 162 or the drain electrode 164. In FIG. 2F, the case in which the first functional electrode 182 is connected to the drain electrode 164 is illustrated by way of an example.

While it is illustrated in FIG. 2F that the upper gate electrode 180 is divided into two regions due to a position of its cross-section, it can be seen from FIG. 1A that the upper gate electrode 180 has one pattern.

Subsequently, an interlayer insulating layer 190 is formed on the entire surface of the resultant structure in which the upper gate electrode 180 and the first functional electrode 182 are formed. The interlayer insulating layer 190 causes the upper gate electrode 180 and the first functional electrode 182 to be electrically isolated from each other.

As illustrated in FIG. 2G, the interlayer insulating layer 190 is etched to form an opening C4 exposing the surface of the first functional electrode 182. In FIG. 2G, the interlayer insulating layer etched when the opening C4 is formed is indicated by 190A.

As illustrated in FIG. 2H, after a predetermined material layer 200 is formed on the first functional electrode 182 exposed through the opening C4, a second functional electrode 210 is formed on the material layer 200. Here, the material layer 200 may be the organic light-emitting layer of an OLED display device, the liquid crystal layer of a liquid crystal display device, or the spacer of a sensor. For example, when the material layer 200 is an organic light-emitting layer, it may be formed of a single layer, such as a hole injection layer, a hole transport layer, a hole blocking layer, an electron blocking layer, an electron injection layer or an electron transport layer or a stacked layer thereof. Further, the second functional electrode 210 may be the common electrode of an OLED display device or liquid crystal display device or the upper electrode of a sensor.

As a result, the semiconductor device according to an exemplary embodiment is formed.

For example, in an OLED display device, the first functional electrode 182 (a pixel electrode), the material layer 200 (an organic light-emitting layer) and the second functional electrode 210 (a common electrode) constitute an organic light-emitting device. Here, the first functional electrode 182 may be an anode, and the second functional electrode 210 may be a cathode. Alternatively, the first functional electrode 182 may be a cathode, and the second functional electrode 210 may be an anode. Here, the anode may be formed of a transparent conductive layer such as an ITO layer, an IZO layer or an ITZO layer, and the cathode may be formed of Mg, calcium (Ca), Al, silver (Ag), barium (Ba) or an alloy thereof.

For another example, in a liquid crystal display device in which a liquid crystal display is applied, the first functional electrode 182 may correspond to a pixel electrode, and may be formed of a transparent conductive layer such as an ITO layer, an IZO layer or an ITZO layer.

In this case, a process of forming an alignment layer on the first functional electrode 182, a process of forming a short, a silant and a spacer thereon, a process of disposing a color filter substrate including a common electrode as the second functional electrode 210 thereon, and a process of injecting liquid crystal thereinto are sequentially performed, so that the liquid crystal display device is completed.

As still another example, in a contact-type sensor, the first functional electrode 182 may be a lower electrode of the sensor, may be formed of an ITO layer, an IZO layer or an ITZO layer. The first functional electrode 182 may be formed of a single layer such as an Al layer or an Al alloy such as an Al—Nd layer or multiple layers in which a Mo alloy layer and an Al alloy layer are stacked.

In this case, a spacer is formed on the first functional electrode 182, and a resin film that includes the upper electrode as the second functional electrode 210 and exhibit piezoelectric properties is formed thereon, so that the contact-type sensor is completed.

Obviously, the shapes and materials of the upper gate electrode 180, the first functional electrode 182, the material layer 200 and the second functional electrode 210 may be appropriately changed depending on use of the semiconductor device.

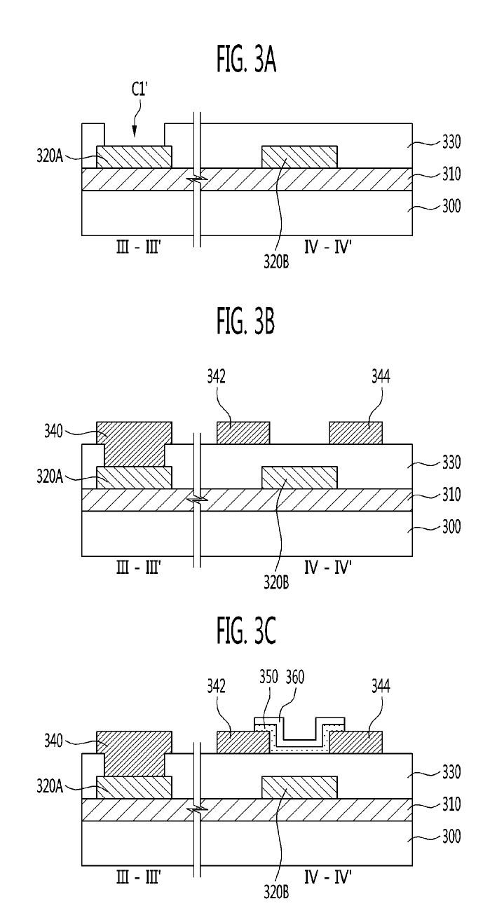

FIGS. 3A to 3C illustrate a method of fabricating a semiconductor device according to a second exemplary embodiment. In the figures, cross-sectional views taken in third (III-III′) and fourth (IV-IV′) directions of FIG. 2A are illustrated for convenience of description.

In the first exemplary embodiment described above, after the channel layer is formed, the source electrode and the drain electrode are formed. However, in the second exemplary embodiment to be described below, after source and drain electrodes are formed, a channel layer is formed. Comparing the first exemplary embodiment with the second embodiment, a repeated description will be omitted.

As illustrated in FIG. 3A, after a buffer layer 310 is formed on a substrate 300, lower gate electrodes 320A and 320B are formed on the buffer layer 310. Afterwards, a first gate insulating layer 330 is formed on the lower gate electrodes 320A and 320B, and then the first gate insulating layer 330 is etched to form a first contact hole C1′ partially exposing a surface of the lower gate electrode 320A.

As illustrated in FIG. 3B, a conductive layer for a contact is formed on the first gate insulating layer 330 in which the first contact hole C1′ is formed, and then is etched to simultaneously form a contact plug 340, a source electrode 342, and a drain electrode 344.

Here, the source electrode 342 and the drain electrode 344 are formed above the lower gate electrode 320B, and are formed to partially overlap the lower gate electrode 320B. That is, the source electrode 342 and the drain electrode 344 are formed at a predetermined interval so as to secure a region where a channel layer is to be formed, and the source electrode 342 is formed at a position overlapping an end of the lower gate electrode 320B, and the drain electrode 344 is formed at a position overlapping the other end of the lower gate electrode 320B.

As illustrated in FIG. 3C, a material layer for a channel and a passivation layer are formed on the entire surface of the resultant structure on which the contact plug 340, the source electrode 342 and the drain electrode 344 are formed, and then is patterned to form a channel layer 350 and a passivation layer 360.

Here, the channel layer 350 may be formed on the first gate insulating layer 330 between the source electrode 342 and the drain electrode 344, and be patterned such that sidewalls and top surfaces of the source electrode 342 and the drain electrode 344 are partially covered to electrically connect the channel layer 350, the source electrode 342 and the drain electrode 344 to each other.

Subsequently, although not illustrated in FIG. 3C, processes of forming the second gate insulating layer, the upper gate electrode and the first functional electrode are sequentially performed in the same manner as described in the first exemplary embodiment.

According to the present invention, the contact plug 160, the source electrode 162 and the drain electrode 164 are formed at the same time by the same process, and the upper gate electrode 180 and the first functional electrode 182 are formed at the same time by the same process, so that the semiconductor device including the dual gate transistor may be fabricated without addition of separate mask and thin film deposition processes.

Therefore, the application of the dual gate transistor not only enhance the field effect mobility but also reduces the channel resistance, so that the characteristics of the semiconductor device may be significantly improved with neither an increase in process cost nor a decrease in yield, compared to the related art. In particular, a high-speed, large-area, high-definition display device can be provided, and performance of a sensor may be improved.

Up to now, the case in which one cell includes one transistor is described by way of an example. However, this configuration is merely provided for clarity, and so the present invention is not limited hereto. The present invention may also be applied to the case in which one cell includes a plurality of transistors.

According to the present invention, a dual gate transistor exhibiting a low channel resistance and high field effect mobility can be applied to a semiconductor device. Therefore, an oxide thin film transistor exhibiting high field effect mobility and high reliability in connection with heat, electricity and optical stress is formed, so that a large-area high-definition display device can be provided. In addition, as a result of improving the field effect mobility, a sensor exhibiting enhanced performance can be provided.

Also, according to the present invention, an additional mask or deposition process is not required in fabricating a semiconductor device including a dual gate transistor compared with a conventional process. That is, a semiconductor device including a dual gate transistor can be fabricated using a conventional process without an additional mask.

For example, in a display device, the thickness of a passivation layer interposed between a conventional gate electrode and a pixel electrode is adjusted to be used as a second gate insulating layer or a conventional pixel electrode patterning process is partially changed to simultaneously form an upper gate electrode of the dual gate transistor when the pixel electrode is formed, so that the dual gate transistor can be formed without an additional process.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A semiconductor device comprising:
a lower gate electrode;
an upper gate electrode on the lower gate electrode;
a contact plug interposed between the lower gate electrode and the upper gate electrode, and connecting the lower gate electrode to the upper gate electrode; and
a functional electrode spaced apart from the upper gate electrode and formed at the same height as the upper gate electrode.

2. The device of claim 1, further comprising a source electrode and a drain electrode spaced apart from the contact plug and formed at the same height as the contact plug.

3. The device of claim 2, wherein the functional electrode is connected to the source or drain electrode.

4. The device of claim 1, wherein the contact plug, the source electrode and the drain electrode are formed of the same material.

5. The device of claim 1, wherein the upper gate electrode and the functional electrode are formed of the same material.

6. The device of claim 1, further comprising:
an organic light-emitting layer on the functional electrode; and
a common electrode on the organic light-emitting layer,
wherein the functional electrode is used as a pixel electrode of a display device.

7. The device of claim 1, further comprising:
a liquid crystal layer on the functional electrode; and
a common electrode on the liquid crystal layer,
wherein the functional electrode is used as a pixel electrode of a display device.

8. The device of claim 1, further comprising:
a spacer on the functional electrode; and
an upper electrode on the spacer,
wherein the functional electrode is used as a lower electrode of a sensor.

9. A method of fabricating a semiconductor device, comprising:
forming a lower gate electrode;
forming a gate insulating layer on an entire surface of the resultant structure in which the lower gate electrode is formed;
forming a conductive layer for an electrode on the gate insulating layer; and
etching the conductive layer for an electrode to form an upper gate electrode located above the lower gate electrode and a first functional electrode spaced apart from the upper gate electrode.

10. The method of claim 9, further comprising: after forming the upper gate electrode and the first functional electrode,
forming an interlayer insulating layer on an entire surface of the resultant structure in which the upper gate electrode and the first functional electrode are formed;
etching the interlayer insulating layer to form an opening exposing a surface of the first functional electrode;
forming a material layer on the first functional electrode whose surface is exposed by the opening; and
forming a second functional electrode on the material layer.

11. The method of claim 9, wherein forming the gate insulating layer includes:
forming a first gate insulating layer on an entire structure of the resultant structure in which the lower gate electrode is formed;
forming a channel layer partially overlapping the lower gate electrode on the first gate insulating layer;
etching the first gate insulating layer to form a first contact hole exposing a surface of the lower gate electrode;
forming a conductive layer for a contact on the first gate insulating layer in which the first contact hole is formed; and
etching the conductive layer for a contact to form a contact plug connected to the lower gate electrode and a source electrode and a drain electrode contacting both ends of the channel layer disposed at a position spaced apart from the contact plug.

12. The method of claim 11, further comprising: after forming the source and drain electrodes,
forming a second gate insulating layer on an entire surface of the resultant structure in which the contact plug, the source and drain electrodes are formed; and
etching the second gate insulating layer to form a second contact hole exposing a surface of the contact plug and a third contact hole exposing surfaces of the source and drain electrodes.

13. The method of claim 11, wherein forming the gate insulating layer includes:
forming a first gate insulating layer on an entire surface of the resultant structure in which the lower gate electrode is formed;
etching the first gate insulating layer to form a first contact hole exposing a surface of the lower gate electrode;
forming a conductive layer for a contact on the first gate insulating layer in which the first contact hole is formed;
etching the conductive layer for a contact to form a contact plug connected to the lower gate electrode and a source electrode and a drain electrode disposed at a position spaced apart from the contact plug; and
forming a channel layer on the first gate insulating layer between the source and drain electrode.

14. The method of claim 13, further comprising: after forming the channel layer,
forming a second gate insulating layer on an entire surface of the resultant structure in which the channel layer is formed; and
etching the second gate insulating layer to form a second contact hole exposing a surface of the contact plug and a third contact hole exposing surfaces of the source and drain electrodes.
